(19) United States
(12) Patent Application Publication
(10) Pub. No.: US 2024/0278594 A1
(43) Pub. Date: Aug. 22, 2024

(54) DIVIDING A STRAIGHT OR CURVED LINE INTO "N" NUMBER OF EQUAL SUBPARTS

(71) Applicant: Michael Robert Fried, Oakland, CA (US)

(72) Inventor: Michael Robert Fried, Oakland, CA (US)

(21) Appl. No.: 18/111,904

(22) Filed: Feb. 21, 2023

(51) Int. Cl. B43L 13/00; G06F 30/10

(52) U.S. Cl. CPC B43L 13/002; G06F 30/10

(57) ABSTRACT

Multi-part processes and device with elongated flat members for line end-points, which together can divide a straight or curved line of unknown length into specified numbers of equal sub-parts. This invention significantly extends beyond the limited abilities of various devices and construction techniques, including geometric constructions used over millennia, to subdivide a line into equal sub-parts. The length of any straight-line in a plane can be subdivided into any specified positive natural number of equal sub-parts. The length of any 360° or less arc of a circle in a plane and its subtending central angle(s) can be subdivided into any specified positive integer number of equal sub-parts. Each of the four angles formed when two straight-lines intersect in a plane can be subdivided into any specified positive natural number of equal sub-parts. The specified number for subdivision may be any even or odd positive whole number, including a positive prime number. The multi-part processes and device can be used to produce definite specified fractional subdivisions of a line that are not equal sub-parts of the line. They may be applicable to subdividing arcs of constant curvature that are not circular. This invention can be used to avoid the abstractions in reality and illusions created when objects in the three-dimensional real world are represented two-dimensionally in a plane. The same applies to representations in three-dimensional constructions. This application is a continuation of patent application Ser. No. 16/580,542 in which the examiner found in an amended substitute specification that more than one invention had been disclosed.

### STATEMENT REGARDING PRIOR DISCLOSURES BY THE INVENTOR

None, other than through prior patent application Ser. No. 16/580,542 of which this patent application is a continuation.

### BACKGROUND OF THE INVENTION

In response to an amended substitute specification in patent application Ser. No. 16/580,542, a patent examiner rejecting all claims “because the claimed invention is directed to an abstract idea without significantly more.” In reply, the meets and bounds of the invention were extensively clarified. A patent examiner then indicated in oral and written communications that new subject matter could not be added by way of an amended substitute specification and found that the claims stated additional independent and distinct invention(s). The patent examiner did not state how the purportedly new independent and distinct invention(s) differed from the original invention, but rejected all claims. This application is a continuation of patent application Ser. No. 16/580,542 which is incorporated into this patent application in its entirety by reference.

Below is a modest history of line subdivision that expresses the limitations of its development over millennia. In contrast, the significant advancements this invention introduces to line division are contained in the description of the invention further below following this background.

More than 2,500 years ago, the genius Euclid consolidated the works of earlier mathematicians with his own construction techniques and axioms in the volumes of his book, Elements. Euclid has contributed more to the understanding and use of geometric construction than most anyone has or possibly ever could. The tools of Euclid's geometric construction processes were the compass and straightedge already in use in the mathematical and real worlds. It is believed that Plato objected to constructions which involved the use of any mathematical instrument other than an unmarked straightedge and compasses. (Yates, “The Trisection Problem,” 1942). Euclid's Elements included extensive mathematical rules and construction technique, adopting Plato's tool limitations to use only compass and straightedge. Apparently Euclid further adopted Plato's limitations on the ways compasses and straightedge should be used in geometric construction (use only the points of a compass or the line of the edge of a straightedge) as opposed to all manners of their use available in the real world. Such artificial limitations meant Euclid's geometric construction techniques abstracted reality and were incomplete. For example, Euclid's construction methodologies were unable to address the majority of geometric construction possibilities involving subdividing lines into specific numbers of designated parts. While Euclid's construction techniques facilitated the bisection of curved arcs, angles and straight-lines, Euclid offer no universally workable process to construct the division of a straight or curved line by any prime number higher than 2.

In 1837, French mathematician Pierre Wantzel published a paper that included a proof that the classic geometric problem of trisecting an angle was impossible to solve using Euclid's geometric construction. Wantzel, Pierre Laurent (1837) “Recherches sur les moyens de reconnaître si un Problème de Géométrie peut se résoudre avec la règle et le compas” (Investigations into means of knowing if a problem of geometry can be solved with a straightedge and compass), Journal de Mathématiques Pures et Appliquées (Journal of Pure and Applied Mathematics) in French, 2: pp. 366-372.

Equal subdivisions by positive whole numbers are very rare (as demonstrated by the millennia old “trisecting an angle” problem) except when a special relationship exists between a circular arc and/or its subtending angle and their circle. A specific relationship for division by 3 exists when an arc is exactly three-fourths of the length of a circle's circumference and thus the central angle is 270° (three-fourths of the 360° circle). The remaining circumference that is not part of the arc is 90°, the equivalent of one-third of the arc. Odd number equal subdivisions of a full 360° arc of a circle occur at all vertices of an inscribed odd number-sided regular cyclic polygon. The points where the vertices meet the arc of the circle mark the points where the arc is subdivided into the number of equal parts as the number of sides of the polygon, i.e., an inscribed pentagon divides an arc of a circle into five equal segments and an inscribed heptagon (7 equal segments) divides the circle into 7 equal sub-parts. The problem is that no universal methods had existed to inscribe any odd number-sided regular cyclic polygon.

Particularly implicated here is absence of Euclid's geometric construction to provide for an accurate subdivision in a plane of a straight-line and the line of an arc of an angle of a circle: (1) into any odd positive integer number of specified equal sub-parts, (2) into any even positive integer number of specified equal sub-parts other than into a 2ⁿ positive integer number of equal sub-parts, and/or (3) by a prime number other than 2. Over the millennia, most stopped trying to equally divide a line when they could not get past the hurtle of its division by three (the classic “trisecting of an angle” problem). What was often missed is twofold. Dividing a line into three equal parts should not be a gigantic problem. The inability of Euclid's geometric construction to resolve it made the question of trisecting appear quite “huge.” Little had been attempted to identify the broader construction problem, let alone recognize its magnitude. Development of universally applicable methodologies for equal divisions (including sub-dividing into 3 equal parts) arise in the question: “How do you subdivide a line into any specified number of equal sub-parts?”

When the mathematical concept of geometry was first formalized by Euclid in Elements (circa 475 B.C.E.) and without defining the terms he would use to do so, Euclid defined a general line (straight or curved) to be a “breadthless length” with a straight-line being a line “Which lies evenly with the points on itself.” In 1645, mathematician Pierre Mardele of Lyon, France, explained Euclid's lines in old French that translates into English as the “first species of quantity, which has only one dimension, namely length, without any width nor depth, and is nothing else than the flow or run of the point which will leave from its imaginary moving some vestige in length, exempt of any width. The straight line is that which is equally extended between its points.” Mardele, Pierre (MDCXLV, 1645) “Les quinze livres des éléments géométriques d′Euclide Megarien, traduits de Grec en François, & augmentez de plusieurs figures &demonstrations, avec la corrections des erreurs commises és autres traductions” (“The fifteen books of the geometrical elements of Euclid Megarian, translated from Greek into French, & increased by several figures & demonstrations, with the correction of errors committed in other translations”), Lyon pp. 7-8.

In modern mathematics, given the multitude of geometries, the concept of a line is closely tied to the way the geometry (mathematics) is described. When a geometry is described by a set of axioms, the notion of a line is usually left undefined, with the properties of lines determined by the axioms which refer to them. This flexibility also extends beyond mathematics and, for example, permits physicists to think of the path of a light ray as being a line. By most geometric definitions a line has no width.

What is often ignored about Euclidian definitions is that their use in Euclidean geometric constructions can produce images that are contrary to the Euclidean definitions of what the images are supposed to represent. We can all see that the lines produced by Euclidean geometric constructions (whether drawn in sand as originally, or on some other surface which may include some form of a piece of paper) are not of “breathless length.” In addition to length, these lines have at a minimum the width of the implement drawing them (such as the width of pencil lead used) and may also include the depth made by the impression (as from a stick drawing in sand).

Even before history was recorded, people faced the problem of dividing real world things into equal parts for a variety of purposes including for potential use in construction projects, divvying up food and other things, the acquisition and distribution of natural materials, and in manufacturing a countless number of products. The shortest distance between the opposite ends of a wood board, stone, or some other material is a straight-line. For example, with the length of a standard wood board, that straight-line could start from any one of numerous points along the width of a square cut end of the board to travel the shortest distance to the corresponding point on the opposite square cut end of the board. A simple real world method to find the shortest distance is to attach a string to one square cut edge of an end of a board, and tautly extended a loose end of the string across the similar edge on the opposite square cut end of the board, then move the taut string extension along that similar edge until it reaches its shortest length. That shortest string length of the string is the length of the board.

As the lines used by this invention can start from or be applied to objects in the real world, Euclid's definitions may differ than as used herein. As indicated above, Euclid defines a “general line” as “breathless length” and a “straight line” as a line “Which lies evenly with the points on itself.” Using the example above of measuring the length of a wood board with string, the starting point of the string could be any place along the width of a square cut edge of the wood board. The length measured by the string would apply to the entire board. String is not of “breathless length,” and in addition to length, would have both width and height.

For general purposes here, a line may be defined as the distance a point passes from one end-point of a line to the other end-point of that line. In a plane (a flat two-dimensional surface), the distance a point that passes between two points can be a straight-line, a curved line, or any combination of both. The end-points do not define length or shape of a line as it can meander in any manner between its end-points, with the end-points only determining where a line starts and ends. As example, the straight-line of a chord of an arc is of shorter length between its end-points on an arc than is the length of the arc itself between those same end-points. Unless a representation of a plane is drawn so that a straight-line is parallel to a coordinate axis of the system, all lines passing between two end-points pass two-dimensionally in the plane and can meander forever between its specific two end-points without reaching infinite length. The length of a three-dimensional line when measured two-dimensionally may be distorted because its two-dimensional representation may not include an accurate representation of the actual distance it travels in the third-dimension.

More than 5 millennia ago in ancient Babylonian times, the mathematical process of geometric construction began to evolve using three dimensional tools (a compass and straightedge) to make two dimensional drawings in a plane as representations of what should be applicable in the real world. The two points of a compass could be used to mark the end points of a line. If one of those compass points remains in place at the end of a line drawn with straightedge and the other point marking the other line end was rotated 360°, a complete circle could be drawn with the length of the original line as radius. Babylonian drawings included a variety of intersections of straight and curved lines.

The Babylonians developed a “halfing method” that could be used to construct some equal sub-parts of arcs of constant curvature. They first halved the line of the original arc by drawing a chord (straight-line) from one end of the arc to the other. The chord was then bisected with a perpendicular line. The point of intersection of that perpendicular line with the line of the original arc divided the arc in two (such subdivision can be thought of as 2¹ number of equal sub-parts). Thereby, the initial subdivision of any arc of constant curvature by the Babylonian “halving method” should create two equal sub-parts.

To bisect a chord, compass points are placed at each of its two ends. With one end-point remaining place, the other end of the compass is swung around to draw a circle. The process is repeated from the chord's other end. The two circles formed intersect at two points (one above and the other below the middle of the chord). A straight-line drawn between the two intersection points will perpendicularly bisected the chord.

The Babylonian “halfing method” worked for constructing a complete subdivision of an arc into a specified number of equal sub-parts only when the desired number of equal sub-parts was a power of the number two (2ⁿ where the exponent “n” is a positive integer), i.e., 2=2¹, 4=22, 8=23, 16=24, 32=25. To complete a 2ⁿ number of subdivisions, each of the half arcs created in the first subdivision was halved again. [A new chord was drawn between each arc end and its newly found center point, then each of these two new chords was perpendicularly bisected with its bisector intersecting the half arc at a point dividing the half arc in two.] The process repeats on each new sub-part constructed until the desired number of 2ⁿ equal sub-parts had been reached.

But, ancient Babylonian geometry construction techniques were stymied by subdivision of a line of an arc into an equal number of sub-parts when the positive integer of sub-parts desired was not a “2ⁿ” number of equal parts. Whole numbers that are even by definition have a factor of 2, but most even positive integers do not have 2ⁿ as their only factor. As example, 2¹=2 and 2¹⁰=1,024, which means that only ten “2ⁿ” even positive integers exist from the number 1 to the number 1,024 (2¹⁰). As half of all of the positive integers in the range from 1 to 1,024 are even numbers, that range has some 512 even numbers. And that does not include the additional 512 odd positive integers ranging from 1 to 1,024 into which numbers of equal sub-parts an arc could be subdivided. Going further, as the positive integer exponent “n” in 2ⁿ increases beyond “10,” the disparity of functionality of the Babylonian “halfing method” as a geometry construction processes increases ever more greatly.

Each positive integer that is even, but is not a “2ⁿ” positive integer, has a factor of at least one odd prime number. [Prime numbers are numbers divisible only by themselves and the number 1.] Only 73 prime numbers (including the number 2) exist between 1 and 1,024 (2¹⁰). Ancient Babylonian mathematicians could initially divide any arc of a circle in a plane into half (that's 2¹ number of times, e.g., into a “2ⁿ” even positive integer number of sub-parts where the exponent “n”=1). But, going further, for example, if they wanted to construct six (6=2×3) even positive integer equal sub-parts of an arc, each of the half arcs initially formed by their “halfing method” would have had to be divided into thirds. That's the classic trisection of an angle problem the ancient Babylonians and others could not solve.

Looking equal subdivisions by even positive integers another way: 4=22 and 8=23, with the exponent “n” in the equation 6=2ⁿ falling between the powers of 2 and 3. Here, the exponent “n” is not a positive integer and thus outside the ancients' methodology for halving a line into equal parts.

It was not the length of the arc, but the amount of equal sub-parts being sought of it, that determined whether the Babylonian “halfing method” could equally subdivide an arc. Though some arcs of an constant curvature could be divided into any number of 2ⁿ equal sub-parts, the Babylonian “halfing method” did not provide for the construction of an arc into equal sub-parts when the number of equal sub-parts sought was not soley a 2ⁿ number. All other even numbers are composite numbers (a positive integer formed by multiplying two or more smaller positive integers) with an odd prime number as a factor, e.g., 6=3×2, 10=5×2, 12=3×2×2, 14=7×2, 18=3×3×2, 20=5×2×2, 22=11×2, 24=3×2×2×2, 26=13×2, 28=7×2×2, 30=5×3×2.

Prime numbers are numbers divisible only by themselves and the number one. Prime numbers other than 2, when halved, have quotients that are not positive integers. Halving the quotient and repeating the process on each quotient derived will not form an even positive integer of equal sub-parts of an odd prime number. For the Babylonians and their “halfing method,” that meant that no matter how many times their “halfing method” was used to subdivide sub-parts constructed from the previous subdivision, when the number of equal sub-parts sought of the original line was a composite number with an odd prime number as a factor, their “halfing method” could not do it. They knew of no construction methodology to divide a line into a prime number of equal sub-parts other than two.

Under classic construction rules used by ancient Greek mathematicians from the Archaic through the Hellenistic and Roman Periods (most extant from the 7th Century BCE to the 4th Century CE), only a very few lines that formed the arcs of circles could be divided into an even positive integer of equal sub-parts.

Lines of equal length do not have to have identical starting and ending points. Prior to 212 B.C.E., Achimedes devised a proposition to construct three consecutive equal length arcs on an arc of a circle. He drew a chord across a small arc of a circle. Using that chord as the radius of a circle whose center was at one end of the chord, he drew a circle away from the end of the chord until the circle met the arc again. He repeated the process from the new intersection point with the arc to create the third of 3 equal arcs. The first and third chords of Archimedes' proposition were constructed of equal lengths but do not have any common end-points.

Together, the three consecutively placed equal arcs of Archimedes are also a single arc of a circle divided into three. Archimedes was careful to indicate in this one of his propositions that the chords (and the circles created from them) had to be small. He probably recognized that an increase in the number of equal sized arcs to be consecutively placed on a circumference would increase the length of the circular arc they would occupy and that unintended consequences fatal to the operation could follow.

A corollary to this proposition of Archimedes that would resolve its flaw, and be consistent with dividing into equal sub-parts any circular arc of 360° or less, could be stated as: “An arc of a circle may consist of 3 or any other odd or even whole number of consecutively placed equal length sub-arcs, only when the total of the consecutively placed lengths DOES NOT OCCUPY an arc of a circle beyond the length of its 360° circumference.” If the addition of a new equal sub-part would make an existing construction of consecutive equal arcs extend beyond one complete length of the circumference, then part of the new addition would overlap the initial sub-part causing the circular arc to not be equally subdivided.

Though Archimedes' proposition confirms that an arc of a circle can be divided into thirds, it does not produce what he had been been unsuccessfully trying to propose over his years—a geometric construction methodology that would universally divide any arc into three equal parts.

For centuries, mathematicians have unsuccessfully sought to devise a geometric proposition for the construction of a “trisection” and/or disprove that a division by three was possible. Most mathematicians stopped trying to divide a line into three equal parts without reaching resolution and without considering the more encompassing question of “how to divide any arc into any number of equal parts desired.”

In the real world, division by three (and other whole numbers) is not an abstract idea and occurs every day. If you have three pieces of bubble gum in your bubble gum pack, you can eat one, two or all three of them. Likewise, if you have three equal sized parcels of real property, whether they are adjoining or not, then one, two or all three can be devised to another.

Problems often lie in the nature of a subdivision itself. The length of an arc of a circle is one-dimensional while passing through two-dimensions. The length is a variable, as is the whole number of “n” points of equal sub-parts into which one may desire it be subdivided. These functions can be easily be formulized. For example, the ratio (“x”) of an arc's line length to a fixed length of a circumference can be expressed as x=a:C (where a is the arc's length and C is the length of the particular circumference on which the arc lays). The ratio (“y”) of an arc's subtending angle at the center of a circle to the angle of a circle can be expressed as y=θ:C, (where θ is the angle of an arc that subtends at the center of a circle, i.e, the curve of an arc; and (′ is the fixed length of the particular circumference being subtended). Subdividing the arc's length (“a”) and subtending center angle (“θ”) into “n” number of equal sub-parts can be stated as 1/n=a/n/C=θ/n/C.

A more modern use of the 2,500 year old Pythagorean theorem about relationship among the three sides of a right triangle (a²+b²=c²) and its derivative, the Pythagorean trigonometric identity, attempts to find the length of a curve in a plane by connecting points placed on the curve with chords, measuring the length of each chord, and adding the lengths together. The summation of the measured lengths, often called the “cumulative chordal distance,” is supposed to be the length of the curve. No matter how refined in detail that process may be, the results will always exclude that unmeasured part of the arc that remains between the cumulative measured lengths and the end of the arc. That leaves only an approximation of the actual length of the curve.

Functional equations can mathematically define the curves of most any line. They often involve the use of polynomials in one form or another. Even when such equations can be reduced to more simple equations that identify an equal sub-division of a line, such equal division equations are generally of such abstract nature as to not be translatable into a construction technique that can actually produce an equal division of a particular line in question.

In differential geometry according to Gauss and his “Theorema Egregium,” a sphere is smooth surface with constant curvature that is independent of the sphere's embedding in three-dimensional space and that a sphere cannot be mapped to a plane while maintaining both areas and angles, with any map projection introducing some form of distortion. Euclid's Elements essentially defines a sphere as the surface formed by the full rotation of a circle about any of its diameters with any diameter of any great circle as the diameter of a sphere. Any two points on the surface of a sphere fall on the surface of a great circle of the sphere. An infinite number of planes can contain two points on the surface of a sphere, but only one of those planes will contain a great circle.

In the real world, observation of a line drawn between two points usually includes some of the width of the implement used in drawing it (such as the thickness of the graphite transferred to the plane when a pencil is used to draw a line on a piece of paper). When viewed three-dimensionally, usually one end of such a drawn line is closer to the observer than the other end. In such three-dimensional observations, the width of a drawn line appears to vary ever so slightly so that its width at its distant end-point seems smaller than its width at its closer end-point. As the line goes the distance between the two end-points, the width of the line seems to uniformly expand from its distant end-point until it becomes the width of the closer end-point.

In 1932, the article of German mathematician Ludwig Bieberbach (1886-1982), “Zur Lehre von den kubischen Konstruktionen” (“On the theory of cubic constructions”), was published in the Journal für die reine und angewandte Mathematik (“Journal for pure and applied mathematics”), H. Hasse und L. Schlesinger, Band 167 Berlin, pp. 142-146. Bieberbach demonstrates the trisection of any angle of a circle less than 180° by means of a right triangular ruler providing a right angle to three implied Cartesian coordinate systems with origins at the center of at least three circles. Bierberbach identifies the point of intersection of an isosceles triangle with an arc of a circle at the point that marks a trisection of the circular arc of the original angle (e.g, the angle has been trisected).

In 1942, Robert C. Yates' 78 page book, “The Trisection Problem,” was published by Franklin Press, Inc., of Baton Rouge, Louisiana. In 1971, it was photographically reproduced and republished by The National Council of Teachers of Mathematics. Yates presents numerous non-Euclidean methods for trisecting an angle. He provided detailed illustrations and descriptions of mechanical trisectors, some of which include the compasses with three feet devised by H. Hermes in 1883, Ceva's pantograph of 1699 C.E. that in 1831 C.E. was considerably elaborated upon by Lagarrique, Laisant's compasses and other mechanism of 1875, Kempe's trisectors of 1875, Sylvester's Isoklinostat of 1875, and more. Yates also provided detailed illustrations and descriptions of many curves used for trisection, including the Quadratrix of Hippias of Ellis (from the late 5th-century B.C.E.), the Conchoid designed by Nicomedes about 200 B.C.E., Pappus' use of a unit circle and three isosceles triangles with outer end-points determined by hyperbola from about 300 C.E., the Limacon invented by Pascal about 1650 C.E. Yates stated that it was believed that Plato objected to all constructions which involved the use of any mathematical instrument other than an unmarked straightedge and compasses. He added that with the adoption of tools other than those two classical ones and by altering Platonian rules that many interesting and important contributions have been made to the whole field of mathematics.

Patents have been granted that provide for Protractor-like and other devices that can be used to closely approximate the trisection of of an angle. Examples of such patents include the patents of Graham (U.S. Pat. No. 2,892,586), Martin (U.S. Pat. No. 7,469,483) and Kattan (U.S. Pat. No. 9,212,885).

In 2014, Zsuzsanna Dansco released a video, “How to Trisect an Angle with Origami”, MSRI (Mathematical Sciences Research Institute), a Numberphile Film by Brady Haran, which shows the trisection of an angle of less than 180° using the folding techniques of origami.

Like Bieberbach's 1932 general trisection of an angle, the 2021 patent for the Angle Trisector of Rosenfield (U.S. Pat. No. 10,994,569) illustrates a trisection of any angle of a circle less than 180° and includes a Cartesian coordinate system as the origin for at least three circles (each identified in the patent drawings as a “circular portion”). Rosenfield's patent drawing No. 8/21 (also labeled “FIG. 7.” at its bottom right) shows the use of right angles as a proof that the intersection of an isosceles triangle with an arc of a circle marks the point of a trisection of the circular arc of the original angle.

A wide variety of applications, uses and needs for straight and curved lines runs across a multitude of fields.

Lines of data are often transmitted by wire or wirelessly through small modifications to the line of the wave spectrum on which they are sent. The lines of waves often concurrently carrying data records from different data lines. Not all devices receiving a wave transmission need use all of the data being transmitted. A television uses only that portion of the data it receives that can be incrementally read by its limited data reading capabilities, while a recipient computer can be set to read only specific lines of a data transmitted on a wave length intended for it. Programming paradigms for data stream processing can be applied before transmitting a data stream containing data records. Data in varying formats continuously generated from a variety of sources is often processed, then outputted for transmission which may include through the internet. Processing can be arrayed in a manner that simplifies the translations and broadcast of data. Appropriate processing of increments of original lines of data or of lines of data ready for output from data streaming processing can foreshortened the ultimate length of time of simultaneous broadcast of data records.

Lines of encrypted data may be included in transmissions of wave spectrums. While most recipients of encrypted transmissions lack the mechanizations to decode and read encrypted data, intended recipients use a wide variety of devices and processes to unencrypt those portions of such private communications that are for them. As others may have or develop devices and/or processes to unencrypt messages, an issue has always been one of how to limit clean access to confidential information to some while keeping it from others. Encryption can take place before data processing, during data and data stream processing, after data stream processing before transmission, during broadcast, and at any other times data is being collected, assembled, manipulated, or otherwise stored or handled. Encryption may be applied anytime, including when ultimately bundling segments of data increments onto the wave length(s) to be transmitted. Such data increments can be derived, for example, during the processes of applying data streaming program paradigms before they are bundled for output as attachments to wave length(s) for transmission, with the recipient(s) having the means to unbundle such transmissions and decode the combinations of differing parts into which the increment(s) of data were divided. Greater security is provided when each separate message has is own unique combination of encrypted data with the decode transmitted to the intended recipient with the message or by other means.

The drafting of architectural, technical and engineering plans for real estate developments involves an extensive use of lines. Such plans can include lines apportioning space, the structure and design contemplated by the drafters or anything else involved in a project's research and development. Line combination are often formed to assure compliance with government code and regulations, and other factors that may assure safe construction and sustainability of a project after construction has been completed. These may include any combinations of lines for even the smallest residential or commercial building. Plans have been used to advance interior and exterior structure, surface and facade shapes and design, foundations and more. Today, mega construction projects and their uses, as well as their assembly and massive and varying straight and curved line shapes, rival and can even surpass the great construction projects of history. Many of the angles and straight-lines that can be contemplated for a constituent part of surface, facade, or elsewhere in the project can be manipulated by hand-drawings or computer program and inserted into drafts of architectural or other plans to give the drafter greater options for repetitive structure and design. Structure and design often can be prefabricated offsite with savings to onsite construction costs and other benefits.

Astrophysicists and others view the lines of waves of electromagnetic radiation (such as light traversing an area of space) from different locations on earth and through space exploring vehicles. From such observations, they can approximate spacial distances by applying the constant speed that electromagnetic waves travel in a vacuum to what appear as changes in the same area of space when viewed from these different perspectives. Such methods and other methodologies are used in efforts to define the boundaries of our universe. So far, the lines of its boundaries are not sufficiently defined. It is not uncommon to approximate the size and shape of a variety of distances within contiguous space from information like what is seen through telescopes and gathered on other devices or from studies like those into the effects of electromagnetic and gravitational fields on objects. The size, shape and distances between objects within such space are also approximated, with all often viewed on 3-D readers.

Knowing how much of a product is on-hand, and how much of a specific material from which it is made actually remains on-hand or is available, is information used by manufacturers and others to assure supply equals demand. Many products, and the materials from which they are made, are not generic, but rather can have quite precise details for specifications that make them not readily available elsewhere. The information facilitates continuous or other appropriate production without delays. The quantity of material that will be needed for use can be determined from the estimated length of a supply on hand in comparison to the usage rate of specific lengths. That information will provide advance notice of when the supply will be running low or exhausted, giving enough time to reorder without interrupting the flow of production or availability for use. As example, a constituent part of many water heaters is a length of pipe. Water heater manufacturers, as well as some plumbers who install them, buy a variety of lines of pipe including in quantities of 200 feet or more, including in roles. They cut from those lines, lengths of pipe as needed. A small pipe runs out of the top of most tank-type water heaters into a temperature and pressure relief safety valve with a long discharge pipe running out of the valve. Most plumbing codes require a discharge pipe be connected to the value to direct the flow of discharged hot water into a drain. The small pipes coming out of the water heater and the 2-3 inch pipes that contain the safety value can be specialty pipes specifically designed for an individual water heater model, while the discharge pipe need only be sufficient for expelled hot water to go. Absent an adequate supply of pipe to make specialty pipes, production could shutdown and pending orders and anticipated demand not be met.

### BRIEF SUMMARY OF THE INVENTION

Multi-part processes and device with elongated flat members for line end-points, which together can divide straight or curved lines of unknown length into specified whole numbers of equal sub-parts. Specific unequal sub-parts can also be constructed. In essence, the invention takes a line of material or its similar replication, attaches an end-point to an elongated flat member of the device, wraps the loose end around another elongated flat member and back around appropriate flat member(s) until the number of drooping lines between the elongated flat members is equal to the whole number of equal sub-parts desired. The loose line-end is then attached to the elongated flat member reached. The elongated flat members are expanded apart until the drooping loops of line between them transform into straight-lines of equal length. Various elongated flat members of the device can be used for other line division including dividing equal sub-parts of lines already created and creating determinable fractional sub-parts of equal sub-parts. The equal sub-parts created on the device are consecutively placed on a straight-line. That portion of the straight-line on which lays the combination of equal sub-parts is similar replication of the length of the original line, but does not have its curvature. The similar replication is proportionally restored to the length of the original line then transformed to the original line's curve.

This invention significantly extends beyond the limited ability of various devices and construction techniques, including geometric constructions used over millennia, to subdivide a line into equal sub-parts. The length of any straight-line in a plane can be subdivided into any specified whole number of equal sub-parts. The length of any 360° or less arc of a circle in a plane and its subtending central angle(s) can be subdivided into any specified whole number of equal sub-parts. Each of the four angles formed when two straight-lines intersect in a plane can be subdivided into any specified whole number of equal sub-parts. The specified whole number for subdivision may be any even, odd and/or prime number. In many cases, the multi-part processes and device can be used to produce distinct fractional subdivisions of a line that are not equal sub-parts of the line. The invention may be applicable to subdividing arcs of constant curvature that are not circular. This invention can be used to avoid the abstractions of reality and illusions created when objects in the three-dimensional real world are represented two-dimensionally in a plane. The same applies to representations in three-dimensional constructions.

### BRIEF DESCRIPTION OF THE SEVERAL VIEWS OF THE DRAWING

This Patent Application is a continuation of patent application Ser. No. 16/580,542 which has incorporated herein in its entirety. The drawings of application Ser. No. 16/580,542 were accepted by the Patent Office therein. Without modification, those drawings are part of the incorporation into this application of the entirety of that prior application. There are no new drawings. For ease of reference, a true copy of the drawings from the prior application follows the drawing descriptions below. If that is an improper placement of “ease of reference” drawings, these reference drawings would go into an appropriate place that the Office may designate. Though the drawing descriptions below encompass the gist of the drawing descriptions of the prior application, the drawing descriptions below are modified. The numbering of a Figure (“FIG.”) used here is unchanged from its previous use.

The drawings are not to scale, but intended as representations drawn in the simplest of form to convey how the invention including the apparatus (the device used with some of the processes for subdivision of lines) functions and is used during the division of a line into either “n” number of equal sub-parts or into fractional parts that may not be equal sub-parts.

FIG. 1 is a representation of a circle (“C”) and a wave (“W”). Arc lines are labeled “A.” Straight-line sides of the angles formed by intersections of radius of circle “C” are labeled “s”, with one of the angles formed by such an intersection labeled “a.” Angle “a” is also an example of one of the 4 angles formed when two straight-lines intersect intersect in a plane, all of which can be sub-divided into any whole number of equal parts by the invention.

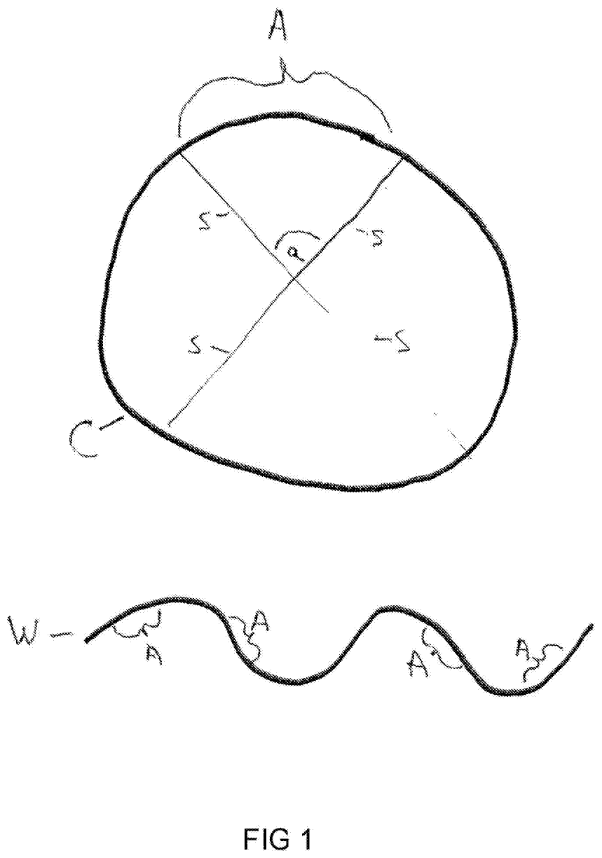

FIG. 2 represents two formats of device used to divide a line into sub-parts. The examples shown are devices with two elongated flat members for line end-points, although such apparatus are not limited to only two elongated flat members. In the top view (labeled “P”), the elongated flat members are directly attached to each other. In the bottom view (labeled “PP”), the elongated flat members are indirectly attached by way of a base. “X” is the approximate point of initial attachment on an elongated flat member of a line, arc (“A”) or similar replication.

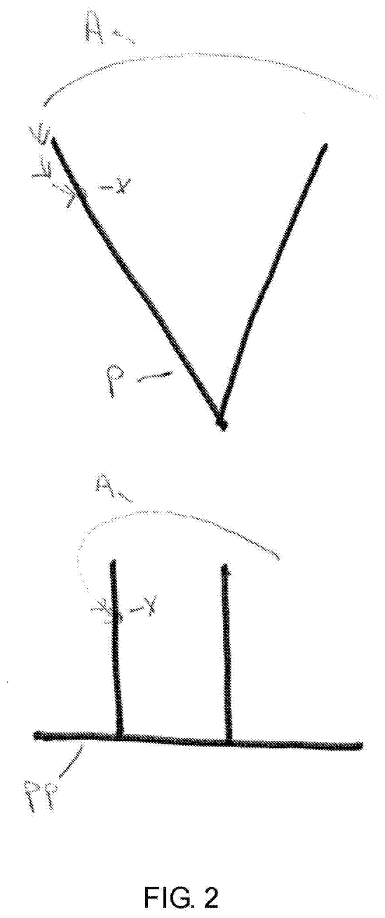

FIG. 3 represents the wrapping of the unattached remaining line, arc (“A”), or similar replication, after one end has been attached to an elongated flat member at “X” as shown in FIG. 2 for a two elongated flat member device (“P”) that has one end of each of its elongated flat members directly attached to each other. Note that the line travels four times between the two elongated flat members (twice in each direction) suggesting that the line is sought to be divided into 4 equal sub-parts.

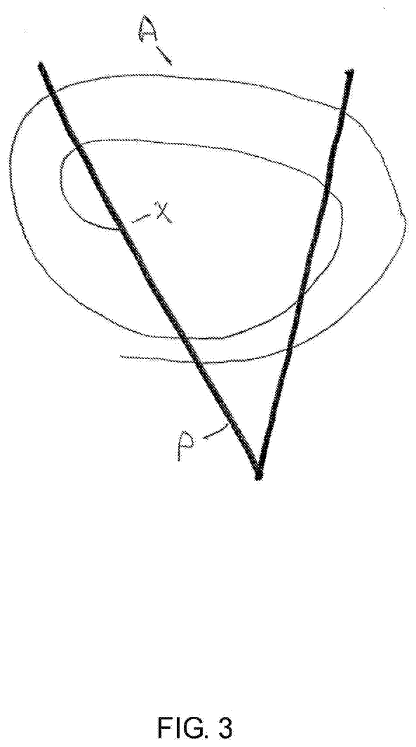

FIG. 4 shows the attachment of the loose end of line or arc (“A”) to the same spot where its initial end was attached (“X”). When both ends of the line are attached to the same elongated flat member, an even number of equal sub-parts are formed on a two elongated flat member device (“P”). In the example shown, that even number of equal sub-parts is 4.

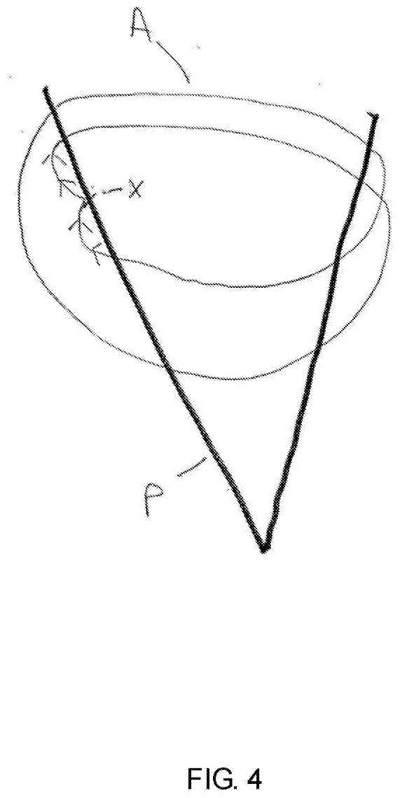

FIG. 5 is an example of using the initial processes to divide a line, arc (“A”) or similar replication, into an odd number of equal parts on a two elongated flat member device (“P”). There is a separate “X” on each of the two elongated flat members, with initial attachment of the line at the “X” on one member and with its ending attachment at “X” on the other. When the ends of a line attach to different elongated flat members of a two member device, the number of equal straight-line segment sub-parts produced is odd. In the example here, there are 5 line segments between the two elongated flat members.

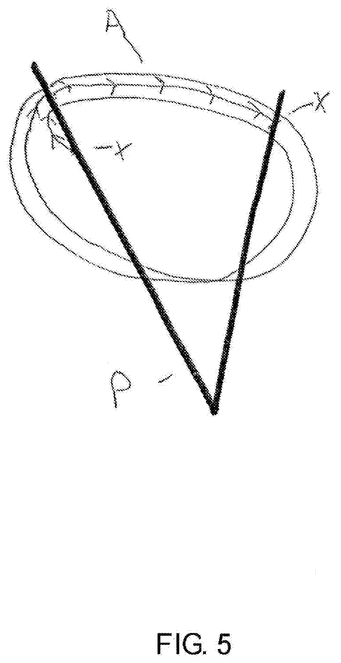

FIG. 6 is an example of where to attach the two ends of a line to produce an odd number of equal subdivisions on the elongated flat members of two member devices (“P” and “PP”) as illustrated in FIG. 2. One end of the line goes to an “X” on one member while the other end is attached to the “X” on the other member. The apparatus works best when the distance (length “1” or height “h”) of “X” (line attachment end-point) on the each of the elongated flat members is approximately the same distance away from where the elongated flat members directly or indirectly attached to each other.

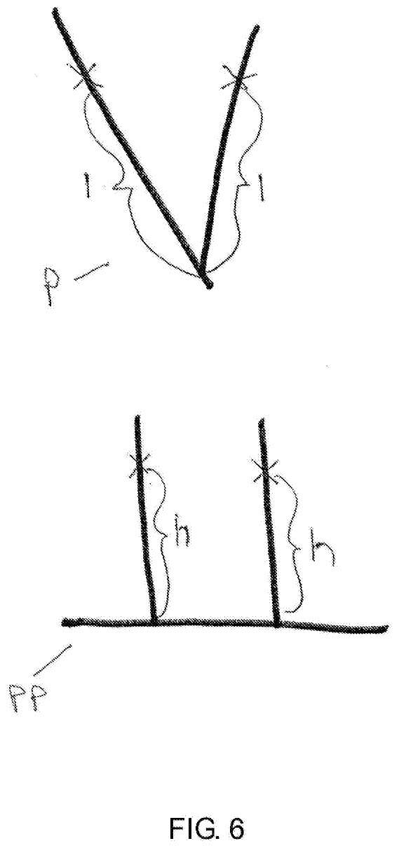

FIG. 7 illustrates the example of two member devices (“P” and “PP”) shown in FIG. 2 after the elongated flat members have been expanded apart to transform the original line or its similar replication into equal length straight-line segments (“sl”) between the members.

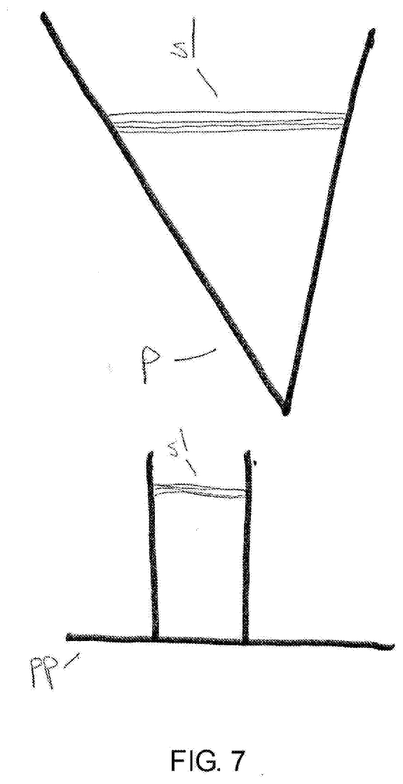

FIG. 8 is a view of transforming one of the equal length straight line (“sl”) sub-parts formed during the processes of FIG. 7 to the curve of the original line.

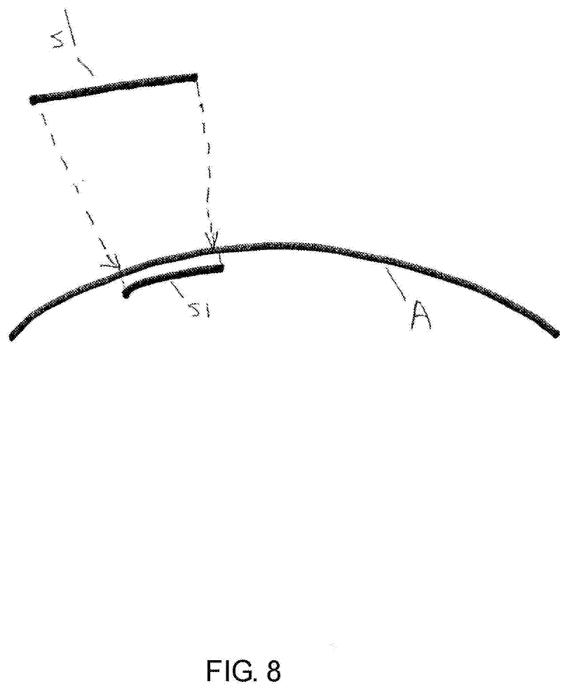

FIG. 9 is a view of the flow (“X”+“Y”+“Z”) for dividing a line or arc (“A”) into three equal segments (“sl”). Note: “X” shows three loosely wrapped line segments between the elongated flat members. “Y” shows that the loosely wrapped line segments of “X” have been stretched out into equal straight-line segments (“sl”) by expansion of the distance between the elongated flat members. “Z” shows the transformation of an equal straight-line segment (“sl”) back to the curve of the line (“A”).

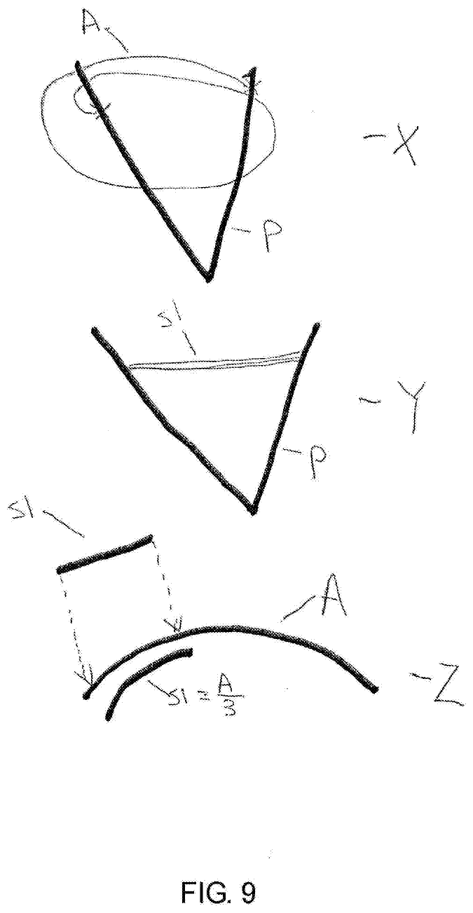

FIG. 10 is a view of finding the center (“c”) of the circle created by perpendicularly bisecting two chords (“sl”) of a circular arc (“A”) and extending the lines (“pl”) of perpendicular bisectors until they intersect, which is at the center of the circle.

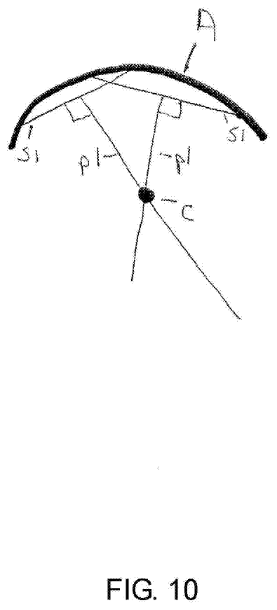

FIG. 11 is an example of a line or arc (“A”) divided into “n” number of equal parts with sides (“s”) drawn from the ends of one of the equal parts (“sl”) through the center (“c”) of the arc's circle to form one of the “n” number of equal angles of the circle (“a/n”).

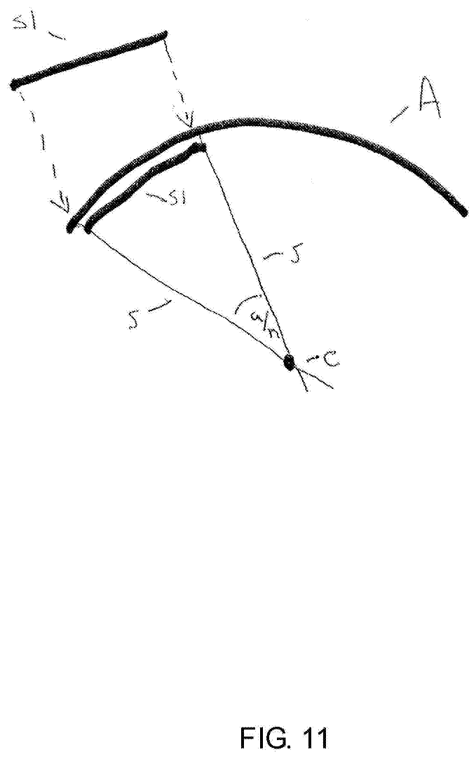

FIG. 12 is an example of a line or circular arc (“A”) forming an angle (“a”) of a circle divided into “n” number of equal fractions. The top two “sl” labeled are two equal straight-line segments pointing to “A”, with three “sl” below “A” being the former equal straight-line segments transformed to the curve of “A.” The angle segments formed are a/n, where n is the number of equal sub-divisions sought. “s” are the sides (radius) of the angles formed with “c” as the center of the circle.

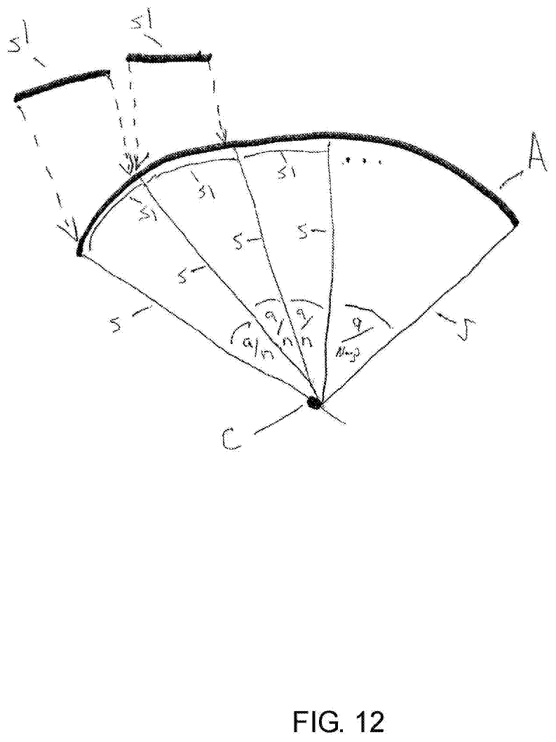

### DETAILED DESCRIPTION OF THE INVENTION

The invention consists of a multi-state process and a device with elongated flat members to mark line end-points.

This Patent Application is a continuation of patent application Ser. No. 16/580,542, wherein the device's elongated flat members to mark line end-points were called “poles” for lack of a better word. “Poles” came from the magnetic North and South Poles, which are used as the Northern and Southern markers of end-points of lines of magnet flux of the earth's magnetic field(s) that run between them.

The device has elongated thin, flat members that are either directly joined together at one end (and not too dissimilar in appearance to the arms or poles of a compass), or indirectly joined together on a base (and/or optional top) with track(s) and in which the elongated flat members can run, or a combination of these attachment methods.

It is the use of elongated flat members, and not what they are called in the patent applications, that is applicable. Elongated flat members are line end-point demarcations for the number of times lines travel between them, with that number of times being of the number of equal sub-parts of lengths of lines that will be processed on the device. Any combination of equal sub-parts created can be further sub-divided into equal sub-parts by appropriate use of the elongated flat members.

The measurement of distances herein is by the relationship of one line to another and not to artificially defined external units. A line is measured as a whole number sub-part or multiple of another line. Its measurement can be increased or decreased by a specified positive fractional sub-part.

As example: if the length of line a is 5 equal lengths of line b, then the length of line b is one-fifth the length of line a. If line c is 5.75% of line d, then line d is a subpart of line d that is 5.75% of its length, which is equivalent to 5 one-hundreths parts of line c plus ¾ of 1 one-hundreth part of line c.

The numerical length of a line need not be unknown. Herein, lines are not measured in fixed units such as radians, degrees, grads, inches, feet or miles. The lines used are proportional to each other. When the measurement of one is known, the measurement of another can be calculated. Using the examples above, if the length of line a is 5 inches, then the length of line b is 1 inch. If line c is a 5.75° angle, then line dis an 100° angle. The ratio of a 5.75% sub-part of a line to the line is 5.75:100.

This invention cannot construct an accurate line from another line if a fractional sub-part is indefinite. As example: while a line can be divided into thirds, when the quotient is defined as 0.33333 ad infinitum, the quotient is inaccurate because a remainder of “an additional 3 and a little more” needs to be added as the last number of the quotient to complete the division. When the subdivision asked for is a 0.33333 ad infinitum subdivision of a line and not specifically one-third, the invention is being asked to include the variable length of “an additional 3 and a little bit more” in the results. No matter how small the difference may be between a line that is of close length with variable length of the line to be created, an accurate line cannot be constructed. At best, only a close approximation of one-third of the line could be formed.

The accuracy of a device depends on the precision of the form of elongated flat members used. An elongated flat member must be of sufficient substance to not break or bend when a line of material or its similar replication is being processed, but not be too large nor too short to inhibit the wrapping and balancing processes. A crude device may use wooden dowels or similar material as elongated flat members. Devices are most accurate when elongated flat members are of minimum thickness and width so that a line being processed does not have its actual length distorted when it passes around the edges of a member. The more a line's length is consumed by the thickness of a member, the less of the line's actual length is available for accurate processing. When elongated flat members are of minimum thickness and a line (or its similar replication) being processed between members is the length of a line with minimal width or height, then the equal subdivisions produced on a device could be as accurate or better than geometric construction drawings on a piece of paper made with a straightedge and compass. Devices that can be generated by computer programs could virtually eliminate the foreshortening of line length that elongated flat members may cause. To increase accuracy, a similar replication may be simulated on an oscilloscope or computer screen (which also can be programmed to restore the shape of a similar replication after any manipulations on it are performed). Likewise, elongated flat members and products of a device and processing by any part(s) of the multi-part process, as well as any products produced on and off of the device by such processing, may be simulated by computer program for use and greater accuracy.

In the direct attachment method, elongated flat members are linked directly together at one end with the other ends movable, and with the movability of unconnected ends being able to be stopped in place relative to each other. Two directly attached members would look like the attached arms of a compass used in making technical drawings of circles. The manner in which the arms of a compass routinely remain in the same place relative to each other unless moved, is one mannerism available to hold elongated flat members in the same place relative to each other. Elongated flat members generally lack the drawing capabilities of compasses, are without compass points, and do not function in the same manner in which compasses have been used.

Devices where elongated flat members are not linked together by direct attachment but by an interlinking pathway/base, member parts extending outward from the pathway/base should be perpendicular to the plane of the pathway/base for best operation. Members should not separate from the pathway when member ends move along it and should easily slide when moved. Elongated flat members must be able to be locked in place (stopped from moving) at any spot along the pathway(s). One end of a member can be permanently fixed (but need not be fixed) at an end of a pathway. When the member is dowel shaped, it can be permanently fixed by being inserted into a hole drilled at a pathway end into the base and glued, screwed, nailed or clamped in place. The remainder of the pathway can be deepened for the other member to easily pass along it. If not dowel shaped, a member can be permanently fixed by an end going into a hole cut at an end of a pathway to fit its shape and, like a dowel shaped member, is fixed in place.

Devices with restrictions for elongated flat members running along a pathway are consistent with popular linkage practices that keep an object running in its track without falling out. Modifications to members by attachment to or change of the shape of a member's end can link the member's end to an adjacent portion of a groove cut into a side of a pathway and running the full pathway length within which the end modifications of the member could pass. The combined width or height of groove and pathway at any one place is greater than the ungrooved portion of the pathway through which unmodified parts of the elongated flat member pole might slide.

An example of an alternative that could be used includes two tracks placed just above the bottom of pathway in the base that run the pathway's full length. The ends of elongated flat members would be modified with a linkage small enough to pass between the two tracks but which would end up on the other side of the tracks in a shape larger than can pass back through the tracks. Linking the members to the tracks prevents separation from the pathway.

Another alternative is a top to the device to hold the elongated flat members in place. A mirror image could be cut into the top the same size of and facing the lower pathway. The mirror image cut into the top is aligned with the bottom pathway so that when one end of a member moves along either pathway, the other end of the member correspondingly moves along the mirror image of the other pathway. Proper alignment of the top and bottom can occur when the planes of the pathway/base and pathway/top are parallel with the connecting members in between perpendicular. When the form of the device is a computer program simulation, an application that keeps the elongated flat members functioning by other means than simulating pole end modifications or attachments could be used.

How a top is attached to a pathway/base or something external should not interfere with operation of the device. A top or base can have any shape as long as it supports its elongated flat members and the material being processed and without causing a member to bend or break. Neither should interfere with a process or its product except as designed for the base to be used. The linkages of members to a top or bottom (even when one is permanently fixed to a pathway) must be sufficient enough to keep the top and bottom in alignment as members slide easily along the pathway(s) and sub-parts are formed. But if a fixed member is too thick, it will distort the length of the line of material passed along it. While adding some other attachment(s) between a base and top may provide the additional support needed to keep them in alignment, such addition(s) cannot interfere with device functions.

A top need not be directly attached to a base but can be attached elsewhere to maintain alignment. When a device is mounted on a table or platform, the top can be attached to an adjoining wall. When a machine performing manipulations on a device and/or directly removes products produced on a device for further use, a top (as well as a bottom) can be fixed to the machine. A point where alignment of top and bottom pathways occurs is usually when right angles are formed by the elongated flat members from each spot along the line of a pathway to the corresponding spot on the opposite pathway.

Elongated flat members need to be locked in place (kept from moving) at times during device operations. A device with members directly attached at one end can be locked in place when an attaching device is a screw with a wingnut that can be tightened (or loosen) as necessary to lock the members in place or permit the free movement of the unattached member ends. Several devices will stop the members from moving on a pathway/base and can be released to facilitate free movement of the poles. A simple wedge that inserts between a pathway edge and a member can secure a member from moving. A member can be even more secure when the wedge edge that touches it is cut in reverse of the member shape where the wedge touches it. Securing a member to one pathway of a device with a top and a bottom would stop the opposite end of the member from moving from the same corresponding spot in the opposite pathway. If movement is not stopped in a pathway when one end of member is secured in the corresponding opposite pathway, then an additional locking device can be used to hold the member in place in the pathway in which it would move. Devises other than a wedge exist can be used to secure a member in place on the pathway including such things as a clamp, screw-type device or lever. Whatever device or technique is used to lock a member in place, it should easily lock and unlock without interfering with device operations or the products being produced on and between the members.

Elongated flat members need not be the same shape, but must be without a design that would inhibit or prevent a line of material (or its similar replication) and the sub-parts being produced from freely moving up and down a member while being processed. When the free movement of a line or its interim line segments on a member is stopped by a member's shape, including to the extent that an interim line segment becomes caught on a member, the processing cannot continue until the glitch is resolved.

The appropriate size of a device depends on how it is being used. Manipulations directly performed by human hands are reasonably accommodated by elongated flat members of 6-8 inches in length with diameters from very small to up to about half an inch. Such devices can have a pathway 8-10 inches long. A pathway's base must be of sufficient size and weight so that the device does not rock or tip over during hand manipulation. A device can be manipulated mechanically and/or the device and its processes can be incorporated into another machine's processes. If so, the device may be significantly smaller or larger depending the size and precision of the other machinery and how products will be taken from the device and/or further used in the mechanical processes. A device can be in the form of a simulation in a computer program with applications to perform the processes used with it. Any stage of the process and/or of the products should be viewable on a computer screen and/or be able to be transmitted to another device for further viewing and/or use of the products produced.

Devices can come in three different formats: as a stand alone, as part of or connected to a machine or other mechanical apparatus, and as simulated by computer program or similar system.

Parts of the multi-state process apply to both direct and indirect use of the of a device, as well as processing that does not involve use of the device. For simplicity of understanding these processes, much of the following provides their use with a device that has only two elongated flat members, though such usage would be applicable to devices with differing numbers of elongated flat members.

A use of a device is during a wrapping process that deforms the curvature of the original line or its similar replication (both of which are referred to in this series of paragraphs as a “line”). The lengths of line segments between elongated flat members can change shape at anytime during the wrapping process to accommodate the passing of the loose end of the line around members (including during the final wrap to reach the member that makes the number of drooping arc line segments between members equal to the number of equal sub-parts being sought). The entire length of the line being processed remains the same throughout regardless of any changes in the shape of its curves.

In the wrapping process, elongated flat members are first placed a short distance apart. That distance should provide enough space between members for segments of the line being processed to be able to droop between members as various line sub-parts are formed during the wrapping process. But the distance between the elongated flat members must be shorter than the estimated length of the straight-line length of an equal length sub-part that will be produced from the line being processed. That distance is less than half the distance members can expand apart from each other.

An end of the length of an original line of material or its similar replication (both referred to in series of paragraphs as a “line”) is attached to an outside edge of one of the two elongated flat members. The unattached end is loosely wrapped around the other elongated flat member, then back and forth between members until the number of uneven line segments between the two elongated flat members is equal to the specified number of equal sub-parts being sought of the line. The loose end of the line is attached to the elongated flat member its reaches that makes that specified number of divisions. At this point in the processing, the shape of the line being processed line has been deformed, but its length has not changed.

In continuing processing on the device, the elongated flat members are moved farther apart. The number of segments between the members will not change. Rather, parts of drooping line segments will shift around the edges of elongated flat members to other drooping line segments as the unequal lengths of line segments begin to balance in length. As the members move further apart, the droopy line segments between them straighten out. The transformation continues until near the end of the elongated flat member separation process. There, line segments begin to overlap until they begin to appear almost as a single straight-line between the elongated flat members. When balancing is complete and no further separation can be made, each line segment between members will have transformed into a straight-line, all of which are of equal length. On completion of the transformation process, one end-point of each of these equal straight-line sub-parts will have been placed at the same point on one of the elongated flat members. All of the other ends of these equal straight-line sub-parts will meet at a single point on the other member. Each of the straight-lines between the two members is one equal length sub-part of the number of sub-parts of the line specified, i.e., collectively these overlapping equal length straight-line segments have the total length of the original line (or its similar replication). If the original line had curves, these straight-line equal sub-parts do not yet have that curve. Details of how parts of the multi-part process transform these straight-line equal sub-parts to the curvature of the original line are explained in paragraphs later down below.

When a similar replication of a line is used instead of the original line, the equal straight-line segments produced on an apparatus may not be the full size of the original, but are at least proportional to the original line's length. If not full size, similar replications and their constituent parts are restored to original line lengths and its equal sub-parts by reversing the ratio of change (the proportional change) from the original line used in the creation of the similar replication.

A line can also be subdivided into a specified fractional length that is not an equal sub-part of the line. As example, while a fractional sub-part of 5¾% of length of a line is an inherent (but perhaps unmeasured) part of a line, such a 5¾% length is not an equal length sub-part. Rather, the number of 5¾% sub-parts that a line can be subdivided is approximately 17.4.

Three stages are involved in processing a fractional length subdivision of a line or its similar replication on a device. The device is used to produce equal length straight-line sub-parts that will be used in the creation of the whole number portion of the fractional length desired. The device is also used to create equal length straight-line sub-parts that will be used to create that portion of the desired subdivision that is less than a whole number. A straight-line the length of the line used in device processing (regardless of whether that of the original line or its similar replication) is drawn independent of the device. The appropriate number of equal straight-line sub-parts created for the whole number portion of the fractional length desired and the appropriate number of equal straight-line sub-parts created for the less the an a whole number portion are transferred from the device and placed on the drawn straight-line in consecutive order (end-to-end). What is produced is a similar replication of the original line containing the specified fractional length desired, with all awaiting further processing that will transform it to the size and curvature of the original line.

Devices with more than two elongated flat members can provide alternatives to separately transferring individual equal length straight-line sub-parts to the drawn line. Combinations of elongated flat members can be used as end points for specific numbers of multiple individual equal length straight-line sub-pars already created between elongated flat members and to subdivide existing equal straight-line sub-parts into additional equal lengths of straight-line sub-parts. In other words, all of the parts needed for a stand alone line with a specified fractional sub-part can be produced on a device.

In the example above of a 5¾% fractional length, the whole number element of the specified length for resulting line is “5%” (5 one-hundredths or one-twentieth) of the length of the original line. The element of the desired sub-part that is less than a whole number is ¾% (three-fourths of one-hundredths) of the length of the original line. The three stages used to create a 5¾% fractional length on a two elongated flat member device follow.

If the original line (or its similar replication) is processed on a device into 100 equal length sub-parts, five of those equal length subdivisions would total 5% of the length of the line being processed. [An alternative is processing the line into 20 equal length straight-line sub-parts, each of which is 5% of the length of the original line. However, this 5% line alternative would not add to the simplification of the production of the remaining ¾% of the original line being sought.]

The remaining ¾% (the less than whole number portion sought in the subdivision) could be produced from one of 100 equal length sub-part of the length of the line being processed) that was produced in deriving the whole number portion of sought in the subdivision. A 1% equal length sub-part can be divided into 4 equal length straight-line sub-parts (each ¼ of 1% of the length of the line being processed), with three of them being ¾% of the processed line).

Independent of the device, a straight-line is drawn in the length of the initial line being processed on the device. A compass is used to measure the length of a 1% straight-line equal sub-part on the device. Beginning at an end of the drawn straight-line (or at some point along the drawn line that leaves sufficient space for the additions), the ends of five of those 1% equal lengths are consecutive marked on the drawn line, end-to-end. The compass is used to measure the length of a ¼ of 1% straight-line equal sub-part on the device. Continuing consecutively from the free-end of the last equal length sub-part marked on the drawn straight-line, the compass is used to mark three of the ¼ of 1% straight-line equal sub-part it measured from the device. [On devices with more than two elongated flat members, a single 5% or single ¾% straight-line sub-part could be created between elongated flat members (as could the entire single sub-part of 5¾%). For example, once the line has been subdivided into 100 straight-line equal length sub-parts, one of those 1% subparts can be further subdivided between elongated flat members into 4 equal straight-line sub-parts (each of which is equivalent to ¼% of the original line processed). Three of those newly created “¼%” straight-lines could be placed between elongated flat members as the ¾% straight-line portion of the ultimate subdivision desired. That “¾%” straight-line could transferred to the drawn straight-line instead of three “¼%” lines. The equivalent of the 5% whole number portion of the total subdivision desired (either as a single 5% sub-part of as five 1% sub-parts) could also be transferred to the drawn straight-line.

In essence, the appearance of a similar straight-line representation of a 5¾% sub-part of a line could be made to appear if elongated flat members of the device could separate so that the distance between the members were equivalent to that of the straight-line length of the original line being processed. That appearance could be viewed if various processed straight-line sub-parts totaling 5¾% of the originally processed line were to be placed between such elongated flat members. But such a construction does not mean that representation is ready for further processing off the device by the multi-state process. Further processing is much easier when using a separate line not drawn on the device. The drawn line is to be the length of the line from which the initial sub-parts were created. Equal straight-line sub-parts totaling 5¾% are to be transferred from the device and consecutively placed on the drawn line. The result is a similar replication of a 5¾% subpart of a line. If the length of a similar replication is not identical to the length of the original line to be subdivided, by proportionality the similar replication is restored as an identity of the length of the original, i.e., both are equal in length. If the original line is curved, other parts of the multi-state process will transform a straight-line similar replication and its straight-line sub-parts to the curvature of the original. In further processing of the “5¾%” sub-part example by the multi-state process, whether restored to full size of the original or not, both the similar replication and its 5¾% sub-part can be transformed to the curves of the original line.

The invention can take the length of a circular arc and the length of its similar replication and transform either into any specified number of equal straight-line segments (i.e., equal sub-parts). The multi-state process can then transpose these equal straight-line sub-parts back to the curvature of the original circular arc. Straight-lines drawn from the points of equal subdivision marked on the circular arc may intersect at the center of the circle, and if so, the straight-lines will equally subdivide the subtending central angle of the arc.

The invention can form a circular arc for an angle without an arc by placing a compass point at the vertex of the angle and swinging the other compass-point around to draw an arc between the sides of the angle. This new circular arc can be processed to equal part subdivision.

The processes of this invention can involve determining whether an arc of even curvature is a circular arc. A diameter of a circle is any straight line that passes through the center of a circle and whose end-points lie on the circle. A radius of a circle is a straight-line half the length of the diameter with one end-point at the center of the circle and other end-point on its circumference. All radius of a circle meet at the center of the circle as do all diameters of a circle. If a chord is drawn on any circular arc (a chord is the straight-line running between two points on an arc), the perpendicular bisector of the chord can be extended in each direction and will intersect the arc at two points, with the perpendicular bisector having run through the center of the circle along the way. The perpendicular bisector drawn from one point on the circular arc to the center of the circle is a radius of the circle, which if extend to a point on the arc on the other side is a diameter of the circle.

The perpendicular bisection of a chord of an arc may be performed by placing the one end-point of a compass at an end-point of the chord and the other compass point at the other end-point of the chord. Keeping one compass-point in place at an end of the chord, the opposite point is swung around to draw a circle. The process is repeated from the chord's other end. Two circles are formed, which intersect at two points (one above the middle of the chord and the other below the middle of the chord). A straight-line drawn between the two points of intersection of the circles forms the perpendicular bisector of the chord. This process will bisect any straight-line.

When extended, all perpendicular bisectors of a chord of an arc of a circle run through the center of the arc's circle. Bisecting three chords of an “unknown arc” can be used to determine whether the “unknown arc” is a circular arc or not. An initial chord is drawn between two points on the “unknown arc.” The chord is perpendicularly bisected, with the bisector extended inward from the arc segment. A second chord is drawn between two points on the “unknown arc.” This second chord perpendicularly bisected, with the new bisector also extended inward. The extended lines of any two bisections of any arc of even curvature intersect at a point which is the common vertex of the four angles created between the straight-lines of the bisectors. A third chord is drawn between two points on the “unknown arc.” The third chord is perpendicularly bisected and the bisector is extended meet the other bisectors. The extended third bisector will either meet the other two bisectors at the same point (the center of the circle) or one or both at someplace else. If not at the same point but someplace else, then the “unknown arc” is not a circular arc.

A circular arc can be constructed from any two straight-lines in a plane come together. The angles formed have their relevant portions of the straight-lines as sides running from the point where the straight-lines meet (which is the common vertex for each of the angles). A circle drawn by compass with one compass-point fixed at the common vertex will construct a circular arc for each angle. Each of the angles is then a corresponding subtending central angle of a circle in a plane.

Similar replications are proportional changes of the size of objects to a size that can be processed and/or made to avoid distortion or destruction of an original shape in processing. The advantage of similar replications is that a change in one element of an object is a proportional change to its other elements. Here, the primary concern is proportional change in the length of a line between its similar replication. As example, when the distance of a perpendicular bisector of a chord of an arc running between the chord and its circular arc is reduced, then both the length of the chord and arc are reduced in proportion to the change in size. Reducing the length of the line of a perpendicular bisector of a chord running from a point from the circular arc to the center of the circle by one-half proportionately reduces the length of the chord and the length of the circular arc by one-half.

A similar replication can be as simple as shaping a string or thread to the shape of an object in a drawing or photograph. The length of the “string” line would have the same length as the shape of the object shown in the picture. The ratio of change in length would be 1 to 1, an identity. Such a similar replication can be done by other means, including by computer program. A camera, and similarly a telescope, basically function on the same principle, that light from one side of a barrier will travel in a straight-line through a small hole in a barrier to the other side to produce an inverse image of the view. The image is the inverse of what is being viewed because most of the light comes from places in the view that are not perpendicular to the location of the small hole in the plane of its barrier. Straight-lines of light from the top of the view will travel through the hole to the bottom of image. Any line of light would travel from its place in the view to its respective inverse location in the image.

The focal length of a camera lens is inversely proportional to the len's field of view (the amount of space the lens can detect). [Longer focal length leads to higher magnification and a narrower angle of view.] As example, a picture of a view on film on the image plane taken by a camera with a 28 mm lens differs from a picture of the view taken from the same spot by the same camera but using a 50 mm lens. While both images will occupy the same amount of space on film (on the image plane), the image on film from the 28 mm lens is that of a field of view that is 50/28th (about 1.8) times larger than the the field of view pictured through the 50 mm lens. That also means that images of the subject matter taken through a 28 mm lens will 56% (the 28/50ths proportional relationship between the two pictures) of the size of the images taken through a 50 mm lens. An object 2.8 inches high on film through a 28 mm lens is magnified to be 5 inches high on the same size film through a 50 mm lens on the same film. This assumes the only change between pictures was the camera lens, with no distortions or other aberrations. The image taken through the 50 mm lens is only a 56% part of the whole picture taken through the 28 mm lens. While it can be restored by inverse ratio of the change ( 26/50) to the size of the image from the 28 mm lens, the 44% of the image from the 28 mm lens view that was not transferred through the 50 mm lens would be gone, absent other methods to retain it.

When the depth of the field of view is greater than the focal length, the image on the image plane will be a smaller proportional two-dimensional inverse picture of the view. The barrier plane and the image plane should be parallel so that the lengths of the lines of light traveling from the view to their respective quadrants on the image plane (film) would not distort the relative shape of complementary and reciprocal images of objects by the change of distance the lines would travel.

A photographic enlarger (or an equivalent device that reduces the size of an image) will change the size of the image taken from a negative by the inverse ratio of the focal length of the camera lens that produced the negative to the focal length of the enlarger. The focal length of an enlarger is the distance from enlarger lens to focal point of the image plane (the photographic paper on which the the negative's image will be latently transferred). Once the photographic paper is developed, a similar replication can be made.

A photographic image of an object that changes the size of an actual object by a specific ratio is also a similar replication. A restoration of such a similar replication to the actual size of an original of the object can usually be made by reversing the ratio of change. An old photograph can be reprinted so that the image in the new photograph is changed by the inverse ratio of the lens focal lengths from new to old photo. If the ratio of change of size of the original to what is pictured of it in a photograph is known, the size of the original may be restored by the inverse ratio. Explanations of various ways to determine the ratio of a change between a similar replication and its original appear in numerous paragraphs of the original application and this continuing application.

The length of equal part straight-line segments of a similar replication, as well as any non-equal sub-parts produced can be restored or transformed to the “full size” of the original line, particularly when the line is a circular arc. The similarity between the original “full size” and its similar replication means that though the lengths and curvatures of the two arcs may not be the same size, the changes in the length and and curvature of a similar replication are proportional changes in the same ratio as original circular arc is to the similar replication. The lengths of equal part straight-line segments produced on a device from a similar replication are also in the same proportion to the replication as would be “full size” equal straight-line parts would be to the “full size” original line whether curved or straight. Most replications are not the same size as a “full size” original and do not have its curvature.

The change from a “full size” original to its similar replication is either a proportional reduction or a proportional increase with the ratio of the change either having “1” as a constituent part (as in 1:3 or 1:n reduction or 3:1 or n: 1 increase, where “n” is a positive natural number) or without having “1” as a constituent part (2:3, 5:7 or x:y, or 3:2, 7:5 or y:x where neither “x” nor “y” equals one) with such distinctions a consideration for determining which processes to apply to the length of an equal part straight-line equal segment of a replication to change it to the “full size” length of an equal part segment of the original circular arc, a straight-line drawn in a plane is used to transform equal part straight-line segments of a replication to the “full size” of the original circular arc (for best accuracy, processes should be performed by computer program with a computer screen showing the operations and from which screen the operator can perform additional functions as needed).

The easiest change of an equal part straight-line segment to “full size” occurs when a similar replication is a reduction of the original line by an equal positive whole numbers of times. That's a reduction ratio of 1:n (where “n” is a positive counting number). That initial reduction in size is reversed by the inverse ratio of 1:n, which is n:1. The length of an equal sub-part straight-line segment of the similar replication (or the entire similar replication itself if not already on a devise) is multiplied by “n” to transform it to “full size.” The length of an equal part straight-line segment of the replication between elongated flat members of the device is measured by a compass. The “full size” length is then constructed on a new straight-line drawn in a plane. One point of the compass is placed on the new drawn line with the compass swinging from compass-point to the next intersection with the straight-line until the initial length of an equal sub-part straight-line segment has been extended “n” number of times across the new line to a point. The starting point and end-points of the construction on the drawn line is “n” times its single length. That constructed length is is equivalent to the length (but not curvature) of a “full sized” equal part of the original line. A 7:1 ratio decrease in the length from original to similar replication is reversed by increasing the length of an equal part straight-line segment of the replication by seven times. That is done by drawing 7 consecutive circles on the new line.

It is not so simple going the other way when the replication ratio from original line to similar replication is an increasing ratio with the number “1” as a constituent part, i.e. a ratio of 1:n (where “n” is a positive whole number). Reversing the change by the inverse ratio (n:1) can be performed by measuring the length of a single equal part straight-line segment on a two elongated flat member device with a compass and marking that measured length on a newly drawn straight-line in a plane (like a flat piece of paper). [On a device with more than two elongated flat members, a similar replication may not have to be removed from the device to perform the coming manipulations with its equal length straight-line sub-parts. The manipulation may be able to be performed between other elongated flat members of a multi-member device.] The measured length placed by the compass on the newly drawn line is processed on a device into “n” number of equal part straight-line segments of the new line similar replication. [To preserve the integrity of measurement in the event of error, it is best not to reuse one of the device's elongated flat members for this second subdivision as that could require removing the existing similar replication from that member.] By the n:1 ratio, each of these new “n” number of equal part straight-line segments is a “full size” new equal sub-part straight-line segment constructed to the same length (but without the curvature) as would be the length of an equal sub-part on the original arc. A 1:7 ratio increase in the length from original to similar replication is reversed by reducing the length of an equal part straight-line segment of the replication to one-seventh its size, which would be the size of each of the seven equal part straight-line segments to be produce, all ready to be transformed to the curve of length of the arc they would occupy.

Reversing the ratio of a change in size (whether it is an increase of decrease) from original to replication when the ratio does not have the number “1” as a constituent part is more complicated, These two scenarios reverse a change of the ratio x:y (where “x” is either less or more than “y” and neither “x” nor “y” is the number “1”, but both are positive whole numbers). The inverse ratio is y:x, which means changing a similar replication or any of its constituent parts by a “y” numbers of times with the product of the “y” increase then divided by an “x” number of times for restoration to “full size” of the original circular arc. The length of a similar replication's equal part straight-line segment is measured from the two-pole apparatus between compass-points. Then, a compass-point is placed on a new straight-line drawn in a plane. That compass-point is the starting point for swinging the compass around from point to point of each intersection along the newly drawn line until the initial length of the replication's equal part straight-line segment has been extended “y” number of times across the newly drawn line (to a point on the new line that is “y” times the single length of a straight-line equal length sub-part). The constructed length on the newly drawn line of “y” times the length of an equal length straight-line sub-part is now divided into “x” number of equal straight-line sub-parts on the device. The equal length straight-line sub-parts now constructed on the device are equal in length (but not curvature) to their corresponding “full size” equal part of the original circular arc. For example, when the initial x:y ratio of change to create a similar replication was decreasing ratio of 2:3, the change is reversed by inverse ratio (3:2) which three equal sub-parts divided in half. Likewise, an increasing ratio of change to a similar replication 3:2, is reversed by its inverse ratio (2:3), i.e., by doubling an equal part straight-line segment of the replication then trisecting the product.

Transforming “full sized” equal length straight-line sub-parts to the curvature of the original arc. One end of a “full size” straight-line equal part segment is attached to an end of the original circular arc with the remainder of that unattached equal part straight-line segment repositioned (placed, bent, pushed and/or pulled) along the length of the original circular arc until the straight-line of this “full size” equal sub-part transforms to the exact curvature of that part of the length of the original circular arc it is to match. The point where that loose end of the equal sub-part falls after it has been fully transformed to the curvature is marked on the original circular arc. From that marked point, the end of another “full size” straight-line equal part is attached and likewise transformed to the curves of that part of the original circular arc it will pass along and marked. The process is repeated until the end of the length of the original circular arc is reached. [Alternatively, after the initial sub-part is transformed to the curve of the arc, With each equal part segment having been transformed to the curvature of the original circular arc and marked on the arc, the original circular arc is now divided into the number of equal parts that were sought. A “full sized” straight line fraction segment is transformed to the curvature of the arc in the manner in which the initial equal sub-part is placed. The result is the fractional segment sought on the original arc. The process similarly applies to most arcs even curvature.

Any angle in a plane can be made a subtending central angle of a circle and divided into equal parts. When a compass-point is placed at the vertex of an angle and the other compass-point draws a circular arc across the straight-line sides extending from the vertex, each arc formed between two sides of the angle is a circular arc with the angle on which it is constructed a subtending central angle of that circular arc. If the angle is one of the four possible angles formed when two straight-lines intersect, each arcs between the sides is a circular arc. Once a circular arc has been created, dividing its subtending central angle into equal sub-parts or into a specified non-equal sub-parts follows the processes described above. Straight-lines drawn from subdivisions of the circular arc to the center of the circle will delineate the sides of the angle subdivisions.

When the curved shape of the arc of a circle in a plane is changed in that plane to some other shape (such as twisted, rounded, or made into an unrecognizable shape), the length of the line that the arc had originally passed along the circumference of the circle between two points on the surface of that circumference remains the same length of the reshaped arc. The shape of the line has changed, but the length of the line has not changed. As example, two dimensionally in the plane of the arc and its circle, the end-points of the arc will move away from each other if the replicated length is transformed from a curved line into a straight line. Since the length of the line has not changed, when the line is straight, its end-points would be at maximum distance apart in the plane.

Similar replication of three-dimensional shapes requires a little more consideration. As example, starting two-dimensionally, if a compass-point is placed at one end-point of a straight-line and the other compass-point at the opposite end-point of the line, when a circle is drawn with its radius the length of the line (i.e., one compass-point could remain fixed at one end of the straight-line and the other compass-point rotated 360° around the fixed compass-point); then a circle would be formed with a diameter 2 times the length of the straight-line. In Elements, Euclid essentially defined a sphere as the surface formed by full rotation of a circle about any of its diameters. Any diameter of any great circle is a diameter of its sphere.

Age-old geometric construction identifies a line between two points on the surface of sphere that runs the shortest distance on that surface as a circular arc on the circumference of a great circle of a sphere. For simplicity of explanation of the applicability of the multi-stage process and the device, a baseball can be used as an example of a spherical shape (rather than an example of a planet in outer-space, though the same principles would apply). String or some other material can be used to make a similar replication of the length of the line that runs the shortest distance on the surface of the baseball between two points on the ball's surface. After the replicating material has been run the surface of the baseball between the two points and adjusted to be the shortest distance between those point on the ball's surface, any excess material is cutoff at each point marking the end of the line. The accuracy of string replication depends on not only how fine the string is, but on the precision of string placement in the shortest path along the line between its ends and on restoration of string equal segments back into the path of the original line or string after processing on a device.

The replication is a very special case as it represents the circular arc of a great circle of the spherical baseball. Such circular arcs can have multiple uses, such as in determining how far away from a viewer the sphere is located, or dividing the material of which a spherical object is composed into sub-parts. Cutting the baseball in half along that special arc through its two special points and on through its other side (assuming its stitching does not interfere) cuts through the center of the baseball to expose the circumference of the great circle on which lays the circular arc replicated by the string. The circular arc can replicated on a piece of paper. The center of its circle can be found by perpendicularly bisecting two chords of the circular arc with straight-lines. These bisectors will intersect at the center of their great circle of the sphere (the baseball). Once the center of the circle is found, the full circumference of the great circle containing the circular arc can be drawn (using the straight-line between any point on the circular arc and the center of the circle as the radius of a circle drawn of a circle drawn by a compass).

The circumference of this great circle of the baseball can be otherwise replicated. Moving a compass-point to each of the two marked line end-points on the ball's surface to measure the straight-line distance between would produce a measurement equivalent to the length of a chord of the circular arc on the baseball. That measurement is transferred and marked on a previously constructed replication of the circumference of the great circle replication with the end-points of the measurement now marking the end-points of the circular arc. When the line of the circular arc, its similar replication(s), or any constituent parts are to be processed on a device with elongated flat members, greater accuracy occurs in simulation by computer program rather than string, as images of the process and device and the products produced can be shown on a computer screen and/or transferred to some other device for further use.

An alternative to destroying the ball is to place it between two parallel surfaces so that it touches each surface without deforming shape. Then, the shortest distance between the parallel surfaces is measured. That is the length of a diameter of the sphere (baseball). A bisection of that diameter produces a radius of the circle, which is then used in the process described above for drawing a replication on a piece of paper.

Replicating and restoring a crumpled three-dimensional line to its original shapes and curves is arduous. The original must not deform replications so much that they cannot be restored to the dimensions of the original. Such dimensions could be lost if the original is changed in any way, particularly when a change in of an original's dimension (a change in height, width and/or length) cannot be easily restored back to the original shape. A similar replication of a crumpled length of a line of material can prevent the original shapes and curves from deforming when processed on a device.

Making a replication of the length of a crumbled line of thread can be as simple as running a thin piece of string from one end of the crumpled thread through and around its various curvatures until the string has run the full length of the thread, then any excess length of string is cut off. Obviously, care must be taken to not deform the shape of the crumpled thread. The crumpled thread is the original and it is highly probable that nothing exactly like it exists onto to which to transform the straight-line sub-parts that will be processed.

The string similar replication is processed on a device into the straight-line sub-parts desired, which are marked on the string at the outside edges of the elongated flat members to denote the location of end-points of sub-parts.

One method of transforming the original crumple line of thread into its sub-parts starts is by removing the entire marked string replication from the device, then transforming the entire marked length of that similar replication along the entire length of the crumpled thread until the replication and its marked sub-parts are repositioned back to the curvature of the length of the crumpled thread.

Another method starts with fixing an end of an individual straight-line sub-part segment produced on the device to an end of the line of the crumpled thread, then transforming the unattached remainder of the sub-part to the curvature of the crumpled thread where it is being repositioned. Repositioning is performed by placing, pushing and/or pulling a string segment until it is transformed to the curves of the original length of thread that the string segment will occupy. The end-point of the string segment is marked on the original at the point where the string's loose end of has been repositioned on the original. That is the point where string segment is has been curved to the original, with the string segment transformed from a straight-line to the length of curved lines of the sub-part it represents. From there, the process of placing and transforming string segments along the remaining crumpled thread is repeated until the end of the crumbled line of thread is reached. When reached, the string will be divided into the specified number of equal parts sought.

The most complex of processes can arise when an original line of material is not amenable for subdivision by use of a simple replication. That can occur when an original object has such diversity in size, shape, design that materials to make a similar replication and/or sub-parts produced from a similar replication could not be placed on the object and/or would deform the object. Likewise, the fragility and access to the object too often makes it inaccessible for direct placement of a similar replication and/or any of its sub-parts. A line across an edge of complex shape may be seen, but most views are insufficient to account for the actual lengths the line travels when the depth of the view varies.

For example, computer or other screens are often used to watch and execute computer programs that focus an x-ray on non-uniform shapes. Electromagnetic emissions like X-rays are unique because many can penetrate objects to view and be focused on spots on the surface, inside and/or on the sides of an object, and can follow the distance of the length of a line of a non-uniform shape and/or see the unseen inside or behind.

An x-ray's focal point can be focused on a spot in an uneven shape and can be moved along an entire length of a line through that non-uniform shape without changing focus. The focal length would remain the same throughout the traverse and parts of non-uniform shape would be in focus and parts would not. Without a change in focus, the line that would start at a point on the uneven shape and travel to the end of the move would be a straight-line and not include the additional lengths of the depth of a line running on what is being view would have. An x-ray's focal length can be adjusted so that what is located at the focal point is in focus. An x-ray can repeat a previous move along an entire length of the same line of movement (from the same starting spot to its end) without changing the location of the move even when its focal length is adjusted. An initial move with a fixed focal length could be repeated with the focal length being adjusted so that whatever is at the focal point is continuously in focus. With proper programming, both the unadjusted and adjusted versions of the focus could be recorded at the same time in one, and not two, traverses of the x-ray across the non-uniform shape.

The ratios of the changes in focal lengths (changes in focus to keep that which is located at the focal point in focus) to the changes in lengths in the moving images without a change in focus (the two-dimensional view) would provide the three-dimensional length of the line the x-ray traveled along the non-uniform shape's line. A similar replication of that length is thus produced.

Similar replications can be made from lines that have only approximated lengths. Astrophysicists view waves of electromagnetic radiation such as light traversing an area of space from different locations on earth and through space exploring vehicles to approximate spacial distances and universal boundaries. Each equal subdivision derived from a similar replication of the image that most accurately approximates the size of a small section of an edge of the universe can be modified to provide a place to chart its contiguous space. An appropriate chart could be constructed when the line of an equal part of the edge is expanded in width and depth to form a grid in which contiguous space can be plotted. The grid making process may be applied to each equal segment. The grids and information inputted into them are monitored and/or modified through computer screens or three-dimensional imaging devices. Such information is like what is seen through telescopes, gathered on other devices, or from studies like those into the effects of electromagnetic and gravitational fields on objects within the grids. The accumulated information helps provide better approximations of the spacial relationships. Equal parts from similar replications of new images of approximations of universe boundary lines can be updated onto the grids and present newer views that lead to further modifications of the view of the edge and its relationships with its contiguous space.

A special case exists in wrapping process where the line of material or its similar replication is not wrapped loosely around elongated flat members. Instead, it is wrapped very tightly to members fixed in place and resolves the question: “How many specific equal segments of known length can be produced from an unknown full length of a line of material that cannot be similarly replicated?” The question usually arises when the shape of a line of material is in a three-dimensional form that blocks full viewing of its actual length. What can be seen of the full length of material can be similarly replicated as an approximation of its length (even though inaccurate). The known length of each of the specific sub-parts to be consumed is of definite length. That known length is similarly replicated in the same proportion (usually a reduction) in length as was the length of the unknown full length line of material. Elongated flat members are fixed in place so that the distance on the device between the far sides members in the same straight-line length of the replication of the segment of known length at the same point on member that is equidistant from where they directly or indirectly attach. One end of the full line approximation replication is attached to a member's far side at that point with the remainder of the approximation replication very tightly wrapping around members until its loose end can no longer reach a member. The number of complete tight line segments between the poles is the minimum number of the segments of known lengths that can be cut from the unknown length of available material. When only what is an estimate of the quantity of material being used over a known period of time, a similar replication of the estimated quantity is substituted between the elongated flat members in place of the known length of a single item. The results of processing would be an estimated amount of material on hand to cover use over a specific time period.

Knowing how the number of specific size of equal line segments available for use in a production process and/or when it takes time to get replacement material from which the segments are cut is particularly useful to avoid slow downs or stoppages in the flow of production. Gold and rhodium wire used in production of some electronic parts can take an extensive amount of time to replace in certain diameters and/or with special alloys. Also the costs of the such materials are not cheap. Manufacturers often seek to minimize outgoing cash flows by stocking only that necessary for continued production. The parts produced from these materials may be for different usages and of different shapes while the amount of wire used in each part's electronic component remains the same. The parts may be made continuously or intermittently manufactured based on demand and varies the rate of usage of the individual specific length line segments. An important consideration for a manufacturer is to have sufficient wire available to avoid reduction in product production. Measurement of the quantity of wire on hand that will be used over a period of time indicates when its time to reorder and reduces expenses incurred in holding surplus material in stock.

Most equal divisions of a replication of an approximated length of a line do not involve such grandiose issues as the size of the universe, but all have a common feature-missing some piece of a puzzle. Knowing the number of equal parts of a specific length that can be cut for use from an estimated length of a supply of material on hand when compared to the usage rate of those equal parts can provide advance notice of when the supply will be running low or exhausted. It can give enough time to reorder without interrupting the flow of use.

A line of data is often transmitted by wire or wirelessly through small modifications to the wave spectrum on which it is sent. The lines of waves often concurrently carrying data records from different data lines. Not all devices receiving a wave transmission have use for all of the data carried (i.e., a television uses only that portion of the data that can be incrementally read by its limited data reading capabilities, while a recipient computer can be set to read only specific lines of data intended for it). By applying programming paradigms for data stream processing before transmitting data records, data in varying formats continuously generated from a variety of sources can be processed and arrayed in a manner that simplifies the translations of data, then outputted for transmission which may include through the internet. If an increment of either an original line of data or the line(s) of data bundled or not ready for output from data streaming processing is more systematically divided into equal parts by use of the invention and/or its products, then the length of time of actual broadcast of data records can be foreshortened as the available line(s) to be broadcast could be divided into equal parts with equal part segments bundled together into shorter modified lines before broadcasting and sent in greater quantity of bundles more simultaneously as part of the wave transmission. Similar use for data encryption applies and may include folding data in a pattern for transmission to a device that decodes the encryption method.

Encrypted data has been included as parts of wave transmissions with intended recipients having means to unencrypt those portions of such confidential communications intend for them. The invention provides methods of even greater security than simply bundling the same equal parts of an increment of encrypted data communications into part of wave transmissions. Rather than using bundles of equal segments derived from only specified numbers of equal divisions of an encrypted data increment on the wave to be transmitted, the increment is divided into several different numbers of equal parts (the full length of the increment remains the same with only the number its equal segments produced varying). These consecutively (or otherwise) attach such differing lengths equal parts to their incremental segment during the processes of applying data streaming program paradigms and bundling the incremental segment(s) before they are outputted as attachments to wave length(s) for transmission. The recipient(s) of such communications would have the means to unbundle such transmissions and decode the combinations of differing equal parts into which the increment(s) of data was divided. Greater security is provided when each separate message is encrypted with its own unique combination of equal parts with its decode transmitted to the intended recipient with the message or by other means.

Lines are extensively used in planning, drafting and correcting architectural, technical and engineering plans for real estate, personal, and other property development, as well as in implementing those plans. Computer programs are often used to assure the lines are an adequate representation of what they are intended to be. A few of the things that lines can represent are available space and its sub-parts, a specific material and its attachment or connectability with other materials in the space they would occupy, and correct usages of materials and construction techniques for safe assemblies and sustainability (as well as code compliance). Though applicable to even the smallest residential or commercial building, such computer programs have advanced interior and exterior structure, surface and facade shapes and design, foundations and much more. Today the use of completed mega construction projects, as well as their assembly and massive and varying straight and curved line shapes, rivals and can even surpass great construction projects of history. With use of the multi-state process and device with elongated flat members, and the inventions' products; any angle or straight-line that can be contemplated for a constituent part of surface, facade, or elsewhere in the project could be manipulated by computer program (and some drafters), then inserted into drafts of architectural or other plans. That gives the drafter greater options for repetitive structure and design, which could be prefabricated offsite with savings of onsite construction costs and other benefits.

The uses of the invention are not restricted to the limited number of examples stated. Rather, it can be used for all enterprises and personal endeavors in which an object that has some length to be divided into sub-parts, and visa versa, when sub-parts are made into their whole. As most activities that use sub-parts are not complex or can be readily performed elsewise, simplicity will demand the invention not even be considered, let alone used.

If the specific line of material to be sub-divided cannot be restored to its original shape after it would be directly processed on the device and a similar replication of it cannot be produced for such processing, then it is not likely that the original line of material can be processed by the invention.

Many of the various construction techniques of the invention have been in existence for decades, centuries and even millennia. Whether those processes were applied individually or in some combination, their use in dividing lines into sub-parts and in reconstruction of lines from sub-parts has been extremely limited compared to the diversity and multitude of such operations that can be performed by this invention. While these general methodologies are in the Public Domain, others found no way and been unable to use these methodologies to construct products produced by the invention.

The phrase, “similar replication,” as used in this application primarily means a straight or curved line. It is a proportional reproduction of one or more dimensions of another line. No claim can be made to the methods of constructing a “similar replication,” except when the construction of the “similar replication” was specifically constructed for use with any of the methodologies of the invention. Such use would include being created for the purposes of being used as the first “similar replication” by an invention process, created for further use during processing, or it is a product of a stage of the processing. The same would apply to “similar replications” under construction. The exceptions are a new use of construction methodologies for a specific purpose to which they have not previously been applied.

What is claimed is:

1. A multi-state process and device with elongated flat members to divide a straight or curved line of unknown length into a specified number of equal sub-parts and into a specified fractional length which is not an equal subpart; the invention does what has not been done before . . .
divide the length of any straight-line in a plane into any specified positive whole numbers of equal sub-parts,
divide any arc of a circle in a plane and its subtending central angle into any specified positive whole numbers of equal sub-parts,
divide any arc of a circle in a plane into a specified definite fractional sub-part,
restore sub-parts of an arc of a circle and of straight-lines in a plane back to the original, divide many arcs of constant curvature into specified equal sub-parts;
the device is composed of . . .
elongated flat members either directly attached at one end (appearing like a compass but without most compass attributes) or indirectly joined at one end together on a base (and/or optional top) with track(s)/pathway(s) for those ends to run, or some combination of both,
elongated flat members that need not be of the same shape, but should be without design that would inhibit processing,
varying size and shape, which depends on use, with manipulation directly performed by human hands accommodated by elongated flat members of 6-8 inches in length, but when mechanically manipulated and/or incorporated into another machine's processes the device could be significantly larger or smaller based on the size of the other machine and the size of the products from the device it will use,
three different formats, as a stand along, part of or connected some other apparatus, and as simulated by computer program(s);
the multi-state process is a series of processes that can be used or repeated in any order, but consists of the following processes in order of most common usage,
The size and shape of the material is determined, as is the number of sub-parts desired, to see if it can be processed directly on a device,
a similar replication (a proportional reproduction of one or more dimensions of another line) of the length of the line of material to be subdivided is constructed if one has not already been provided and/or the original line of material can be easily processed without deforming it,
the elongated flat members are placed a short distance apart (a sufficient distance for segments of the similar replication to droop into, but a shorter distance than the estimate length of an equal straight-line sub-part the drooping lengths will be transformed into),
one end of the length of the similar replication (or the original as appropriate) is attached to an outside edge of one of the elongated flat members,
the unattached end of the similar replication is loosely wrapped around the outside edge of another elongated member, then back and forth between members until the number of drooping segments equals the number of equal sub-parts desired of the original line,
the loose end of the similar replication is attached to the elongated member it reached to make the number of drooping segments the same number as sub-parts desired,
at this point in the processing the shape of the line being processed (the similar replication or original) has been deformed, but the length of the line has not changed,
the elongated flat members are begun to be moved farther apart causing some parts of the lengths of the drooping segments between them to shift around the members as the segments begin to balance in length,
as the elongated flat members move further apart, the drooping segments between them straighten out and will start to appear as overlapping straight-lines between the members,
the process of balancing by expanding the elongated flat members apart is not complete until all segments between them are of equal length with one end of each segment at the same point on one member with other ends of the segments at a single point on the another member-all overlapping and appearing as a single straight-line,
what has been produced so far are equal length straight-line equal sub-parts produced from the line processed (a proportional replication of the original or the original) in the desired number sought of the original, but without the curves of the original,
the equal straight-line equal sub-parts produced are similar replications of the equal sub-parts sought from the original,
equal straight-line equal sub-parts produced from a similar replication are transformed back to the length of the original by the inverse of the proportion (the proportional ratio) that changed the original to the similar replication initially (i.e., increasing the length of a straight-line sub-part to the length of the original can be performed by drawing it on a straight-line in the inverse proportional ratio by which it was reduced, while reducing the length can be performed by further subdividing the sub-part on the device into the reverse of the initial increase, or making the change by combining both processes),
the curves of the original are restored to a “full-size” equal length straight-line equal sub-part sub-part by first attaching one end of the sub-part to one end of the original,
the remainder of the unattached equal part straight-line segment is reposition (placed, bent, pushed and/or pulled) along the length of the original arc until the straight-line of this “full size” equal sub-part transforms to the exact curvature of that part of the length of the original line it is to match,
the point where that loose end of the equal sub-part falls after being fully transformed to the curvature is marked on the original,
from the point the next equal length straight-line equal sub-part is likewise transformed to the exact curves of the original this equal sub-part segment is to match, with its loose end marked on the original,
this process of transforming equal straight-line equal sub-parts is repeated until the end of the length of the original circular arc is reached
the original curved line has been sub-divided into the whole positive number of equal sub-parts desired.

2. The phrase, “similar replication,” as used in claim 1, primarily means a straight or curved line. A similar replication is a proportional reproduction of one or more dimensions of another line. No claim can be made to the methods of constructing a “similar replication,” except when the construction of a “similar replication” was specifically for use with any of the methodologies of the invention. Such use would include being created for the purposes of being used as the first “similar replication” by any invention process, created for further use during processing, or it is a product of a stage of the processing. The same would apply to incomplete “similar replications” under construction. This claim is that the exceptions are a new use of construction methodologies for a specific purpose to which they have not previously been applied.
